(19) United States
(12) Patent Application Publication
(10) Pub. No.: US 2018/0259566 A1
(43) Pub. Date: Sep. 13, 2018

(54) MEASUREMENT METHOD FOR DETERMINING IRON LOSSES

(71) Applicant: Friedrich-Alexander-Universität Erlangen-Nürnberg, Erlangen (DE)

(72) Inventors: Michael SCHNEIDER, Nürnberg (DE); Jörg FRANKE, Marloffstein (DE)

(73) Assignee: Friedrich-Alexander-Universität Erlangen-Nürnberg, Erlangen (DE)

(21) Appl. No.: 15/760,078

(22) PCT Filed: Sep. 9, 2016
(86) PCT No.: PCT/EP2016/071308

§ 371 Date: Mar. 14, 2018

(30) Foreign Application Priority Data
Sep. 14, 2015 (DE) 10 2015 115 447.1

(51) Int. Cl. G01R 31/06

(52) U.S. Cl. CPC G01R 31/06; G01R 31/346

(57) ABSTRACT

A measurement method is for determining core losses, which serve to produce magnetic circuits for electrical machines. In order to allow an accurate measurement that is as quick as possible, it is proposed that a magnetic coupling is produced between a measuring coil connected in a capacitor and a core to be measured, and the measuring coil is then acted upon by an alternating frequency in order to measure the resonant frequency of the resulting resonant circuit and/or the quality of the resulting resonant circuit as a measure of the core loss.

The invention relates to a measurement method for determining core losses according to the features of the preamble of claim 1.

Such a measurement method is known from the specialist article by authors C. F. Foo, D. M. Zhang, “A Resonant Method to Construct Core Loss of Magnetic Materials Using impedance Analyser”. The article resulted from a lecture at the Power Electronic Specialist Conference 1998. It was published in the PESC 98 Record, 29th Annual IEEE, on pages 1997 to 2002 in 1998. The lecture described a method for measuring core losses, in which the core is part of a resonant circuit which is acted upon by an alternating voltage, and a phase shift of the alternating voltage is measured via a network analyser. The phase shift serves as a measure for the core losses. A disadvantage of this method is that the phase difference is already subjected to strong fluctuations in the case of small changes in frequency, especially in the range around the resonant frequency and measurement of the phase angle is therefore costly in terms of measuring technology.

In practice the core losses are measured on samples, in that a primary and a secondary winding are applied to a core taken from a production batch. The transmission behavior of this transformer is then determined, in order to determine the losses. This measurement method is relatively time-consuming and not suitable for continuous recording during production,

From DE 39 07 516 A1 a laminated core is known, as well as a method for producing a laminated core. This laminated core serves as a stator for an electric motor.

Moreover, in practice laminated cores are used as transformer cores.

The object of the present invention is to demonstrate a measurement method for determining core losses, which is sufficiently accurate for industrial applications and at the same time the measurement method can be carried out in a short time, with the result that it is suitable for industrial applications. In particular, the measurement method is meant to allow the continuous recording of all cores produced.

This object is achieved according to the invention by a measurement method with the features of claim 1,

According to the invention, a resonant circuit is produced via a capacitor, a measuring coil and the core to be measured, which is magnetically coupled to the measuring coil. A resonant frequency of the resonant circuit and/or a quality of the resonant circuit are measured or determined, and the core loss is determined on the basis of the measured resonant frequency and/or the measured quality.

The method provides that a magnetic coupling is produced between a measuring coil connected in a capacitor and a core to be measured, and the measuring coil is then acted upon by an alternating frequency in order to measure the resonant frequency of the resulting resonant circuit and/or the quality of the resulting resonant circuit as a measure of the core loss.

A measurement of the resonant frequency of the resonant circuit can be carried out with sufficient accuracy. A measurement of the quality of the resonant circuit can also be carried out with sufficient accuracy. It has surprisingly been shown that the resonant frequency, as well as the quality each represent a suitable measure for determining the core losses. The measurement can be carried out either only on the basis of a resonant frequency determination, or only on the basis of a quality determination, or on the basis of a combination of resonant frequency determination and quality determination.

Through the magnetic coupling of the measuring coil to the core, the core becomes a part of the resulting resonant circuit. As a result of the magnetic coupling between the measuring coil and the core to be measured, the core losses on the one hand have an influence on the resonant frequency of the resulting resonant circuit, in that the cores coupled to the measuring coil, depending on losses, influence the impedance thereof and, on the other hand, have an influence on the quality of the resulting resonant circuit in that, in the case of higher core losses, the quality of the resulting resonant circuit is reduced.

By a “core” is meant such magnetically conductive cores, which serve as core of a winding or coil, and are used for electrical machines, for example motors or transformers. As a rule, such cores or transformer cores consist of ferromagnetic materials. Laminated cores are frequently used, which have a laminated core which consists of a plurality of stacked transformer sheets or magnetic steel sheets. The individual sheets are electrically insulated from each other and are stacked and mechanically connected to form a magnetic steel sheet stack. The insulation is necessary to prevent eddy current losses. In production, a magnetic leakage of such cores results, for example through faulty insulations or deviations in the ferrous alloys used. In the context of quality assurance, it is necessary to record these losses by means of measuring technology.

By “resonant frequency” is meant that frequency of the alternating voltage, with which the resonant circuit formed is in resonance. The resonant frequency of a resonant circuit can be determined with the following equation:

$${f}_{res} = \frac{1}{2 π \sqrt{LC}}$$

fᵣₑₛ: resonant frequency

L: inductance

C: capacitance

The quality of a resonant circuit results as the ratio of the resonant frequency to the bandwidth:

$$Q = \frac{{f}_{0}}{B}$$

Q: as quality

B: bandwidth

f₀: resonant frequency

The reciprocal of the quality of a resonant circuit is also referred to as attenuation. The higher the losses, the higher the attenuation of a resonant circuit. As a rule, the bandwidth of the transfer characteristic of a resonant circuit is symmetrical about the resonant frequency.

It can be provided that, for the measurement of the bandwidth of the transfer characteristic, a first frequency f₁ is determined below the resonant frequency and a second frequency f₂ is determined above the resonant frequency at which the transfer characteristic of the resonant circuit has the same amplitude in each case. Advantageously, a drop in the amplitude of the transfer characteristic from the resonant frequency to f₁ and f₂ by a fixed value, preferably a drop of 3 dB or 6 dB, can be used. By measuring these two frequencies f₁ and f₂, the quality of the resulting resonant circuit can be determined with sufficient accuracy.

The resonant frequency of a resonant circuit is directly dependent on the inductance L and the capacitance C of the resonant circuit. By changing the inductance L or the capacitance C, the resonant frequency is directly influenced.

In an embodiment, the resonant frequency can be determined in that the resonant circuit consisting of the measuring coil, the capacitor and the coupled core is acted upon by an alternating voltage in the range of the expected resonant frequency. The resonant circuit can then be adjusted to resonance by varying the capacitor value. It is possible to calculate back from the differential value of the capacitance of the capacitor to the differential value of the inductance caused by the core affected by the loss, and thus the change in the reluctance of the resonant circuit. This is a direct measure of the core losses.

In an embodiment it can be provided that the frequency of the alternating voltage is changed in order to adjust the resonant circuit to resonance or to determine the resonant frequency. Here, the change in frequency or the deviation of the measured frequency from an expected resonant frequency is a measure of the inductance changed by the core affected by the loss, and thereby, in turn, of the core losses.

In order to be able to determine the range of the expected resonant frequency, it can be provided that, at the beginning of the measurement method, preferably in a preparatory step, a reference measurement is carried out with a reference core in order to determine the expected resonant frequency of the resonant circuit. Alternatively, the expected resonant frequency can also be determined by computation via a computer simulation of the resulting resonant circuit. In the measurement method, the expected resonant frequency can be used as a reference value or as a standard for a core with low losses.

Magnetic coupling between coil and core means that the measuring coil is brought spatially close to the core, or that the core is brought spatially close to the measuring coil, with the result that the magnetic flux of the coil is at least to a large extent, preferably, as far as possible, more than 50% or more than 75% or ideally completely, conducted through the core to be measured. The measuring coil can be brought close or applied directly in a region external to the core to be measured. It can preferably be provided that the magnetic coupling is produced by introducing the measuring coil into an internal space of the core.

In order to obtain a high quality of the measurement results, it can be provided to carry out several measurement procedures relating to one core. In particular it can be provided that the resonant frequency and/or the quality of the resonant circuit are measured at different angle positions of the measuring coil relative to the core, or that, during the measurement of the resonant frequency and/or of the quality, the angle position of the measuring coil relative to the core is varied.

A concept of the invention provides that the measurement method according to the invention is carried out by means of a measuring device. It can be provided that the measuring device has a control and/or display device for the display of measurement results and comprises an alternating voltage generator and a measuring coil for carrying out the measurement.

The measuring coil can be connected to a capacitor to form a parallel resonant circuit. Alternatively, the measuring coil can be connected to a capacitor to form a series resonant circuit.

In an embodiment it can be provided that the capacitor is formed as an automatically adjustable capacitor or has an adjustable capacitor. The adjustable capacitor can be formed in particular as a variable capacitor. In order to automatically adjust the capacitor, the rotor of the capacitor can be mechanically connected to a stepper motor or a servomotor. In an embodiment it can be provided that the capacitor is formed as a capacitance diode or has a capacitance diode.

In order to achieve a particularly high measurement quality, it can be provided that the capacitor has a high quality. For example, a mica capacitor or an air capacitor can be used for this purpose.

In an embodiment it can be provided that the measuring device comprises a network analyser which is connected to the resonant circuit, preferably the measuring coil and/or the capacitor, in order to measure the resonant frequency and/or the quality of the resonant circuit.

As a rule, network analysers which are commercially available record a frequency range which starts at approx. 9 kHz and sometimes reaches far into the MHz range. It has been found that the frequency range of the alternating voltage that is advantageous for the present measurement lies in a range between 5 kHz and 50 kHz, preferably between 9 kHz and 20 kHz,

In order to avoid disruptive influences due to the connection impedance of the network analyser or another connection device, it can be provided that the resonant circuit is connected to the impedance matching unit via a circuit. Preferably, a circuit to the impedance matching unit is connected between the resonant circuit and the network analyser.

In order to guarantee a high reproducibility of the measurement results, it can be provided that the measuring device has a mounting fixture for holding a core and/or the measuring coil. Both the core and the measuring coil can be positioned in the mounting fixture at a defined position and distance from each other. The mounting fixture guarantees that the position of the measuring coil and of the core relative to each other is always formed identical. Thus, deviations of the measurement results due to positional tolerances can be largely excluded.

In order to allow a measurement in different positions, it can be provided that the mounting fixture has an actuator for rotating the core, in order to allow a measurement at different angle positions between the measuring coil and the core. The measurement can be carried out at different angle positions, in that for example the core and/or the measuring coil can be rotated into different angle positions and a measurement can be carried out at each of the different angle positions. Alternatively, it can also be provided that a measurement is carried out during a rotation of the core and/or during a rotation of the measuring coil.

In order to allow an automatic measurement procedure, it can be provided that the mounting fixture has an actuator for rotating the measuring coil, in order to allow a measurement at different angle positions between the measuring coil and the core.

An accurate measurement result can be obtained in that the measuring coil is formed as an air coil. An air coil has a high quality, with the result that it is particularly suitable as a measuring coil.

In order to further enhance the measurement accuracy, it can be provided that the measuring coil is formed as a shielded air coil. Through the shielding, interfering influences due to magnetic or electric interference fields are largely suppressed.

In an embodiment it can be provided that, for suppressing interference fields, the mounting fixture has a shielding mechanism, in order to shield the core and/or the measuring coil.

The measurement accuracy is increased in that, in an embodiment, it is provided that the measuring device has a temperature sensor and is formed such that it automatically corrects the measured value deviations caused by temperature fluctuations. Electronic resonant circuits, especially LC resonant circuits, have a relatively high temperature coefficient. Via the measurement of the temperature by means of a temperature sensor, the measuring device is able to automatically compensate for this temperature coefficient.

An implementation of the invention according to the invention provides a production process for laminated cores, wherein individual magnetic steel sheet slats are provided with an insulation and stacked to form laminated cores. The losses of such a magnetic steel sheet stack are then measured. The measurement method according to the invention has the advantage that the measurement can be carried out during the production of such laminated cores while still within the production line.

In the context of the production of the laminated cores, magnetic steel sheet slats are separated from larger sheets. Through this separation process, burrs can form on the cut edges, which may possibly cause electrical contacts between individual sheets. This results in increased eddy currents and thus increased core losses. Among other things, it is the aim of the invention to record such increased losses. It is thereby possible, for example, to recognize whether corresponding stock tools have reached or exceeded their abrasion limit and need to be replaced.

In particular it is provided that the losses of a laminated core are measured before the laminated core is provided with a winding. This offers the advantage over the measurement method applied in practice that a winding does not have to be carried out on the laminated core in order to carry out the measurement. This means a significant time saving through the measurement method according to the invention.

In order to ensure a high production quality, it can be provided that a limit value is set for the losses of a laminated core, and those laminated cores, the losses of which exceed the limit value, are identified as being defective and/or discarded.

The production quality can be documented in that it is provided that, for the quality assurance, for each measured laminated core, the measured loss value is stored, and several measurement values are statistically evaluated. For example, each batch to be produced can be recorded collectively and the measurement results of a batch can be collected and statistically evaluated and documented. Thus, the high production quality can be documented in the case of each batch to be produced.

Further embodiments of the invention are shown in the figures and described below. There are shown in:

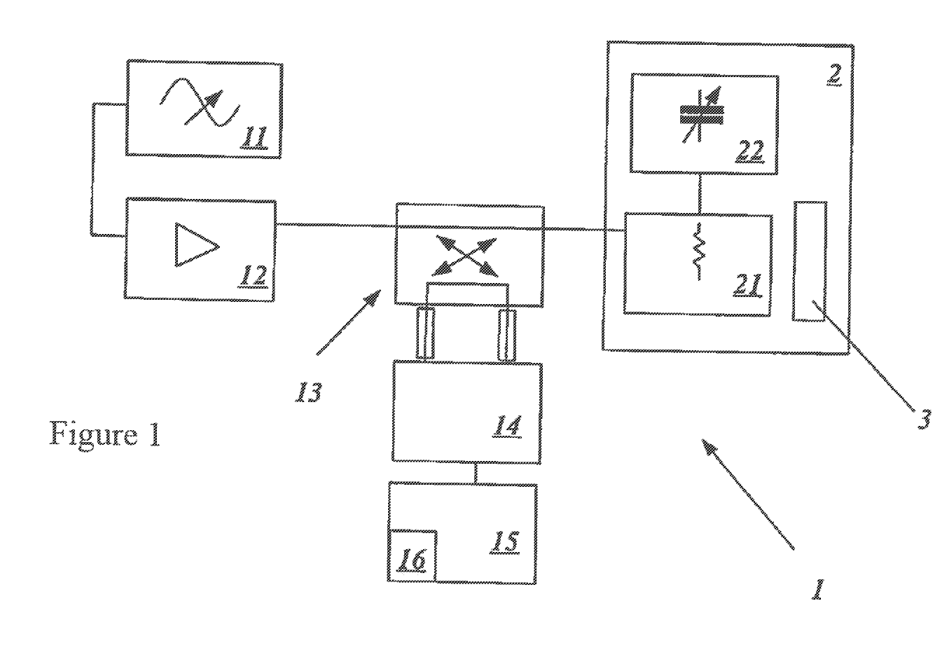

FIG. 1: a schematic block diagram of a measuring device according to the invention;

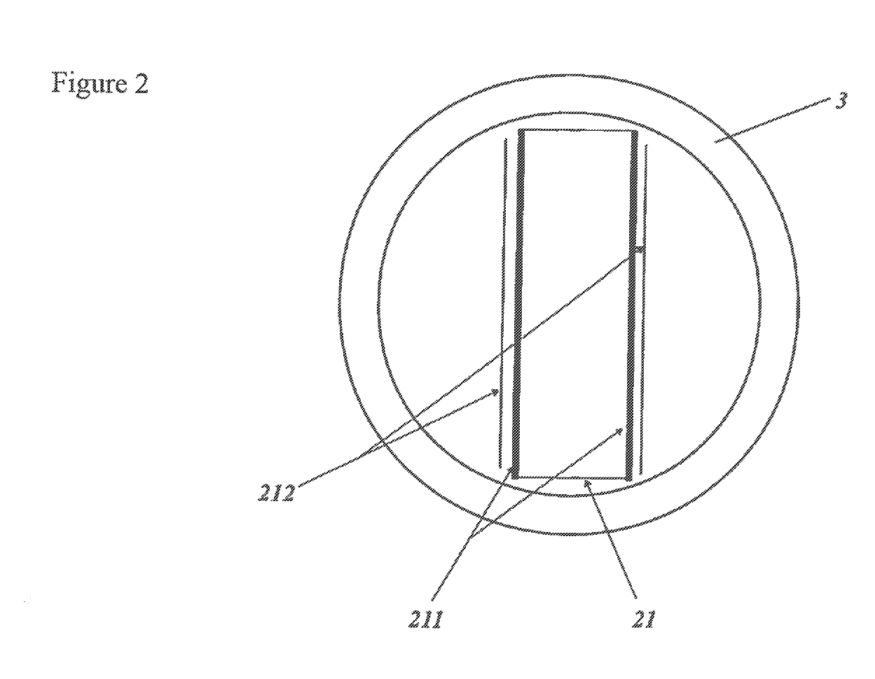

FIG. 2: a schematic structure of a measuring coil in the internal space of a laminated core;

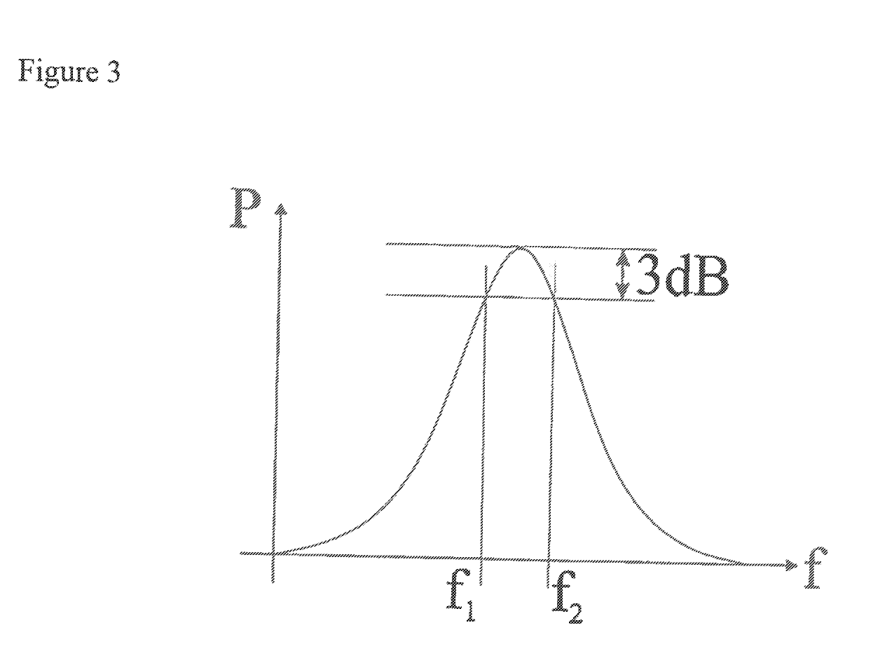

FIG. 3: a frequency transfer characteristic with determination of the 3 dB point;

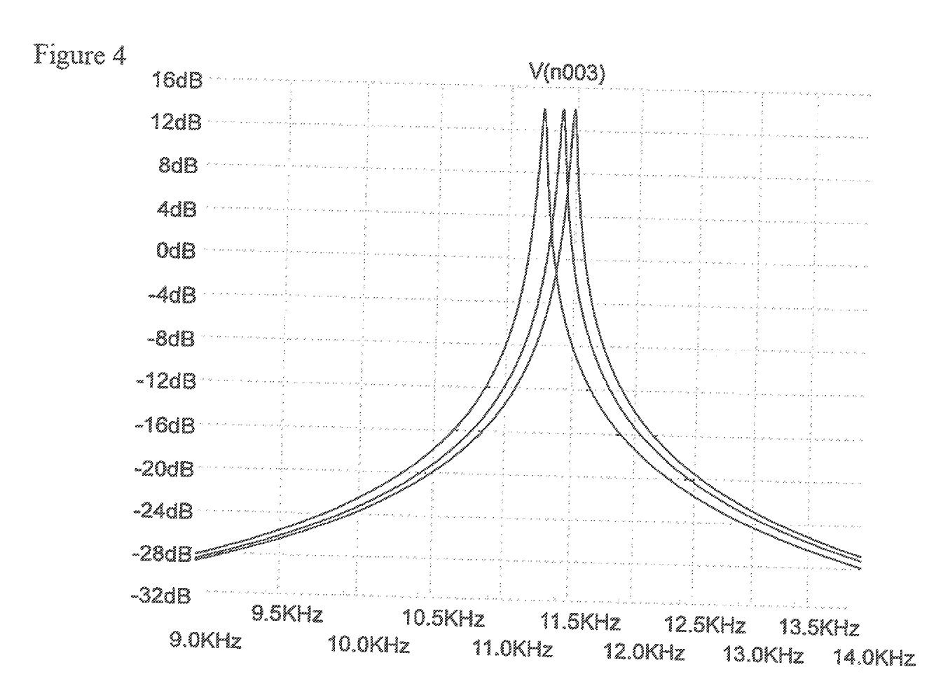

FIG. 4: deviations in the frequency response of a resonant circuit resulting from a change in impedance of the coil;

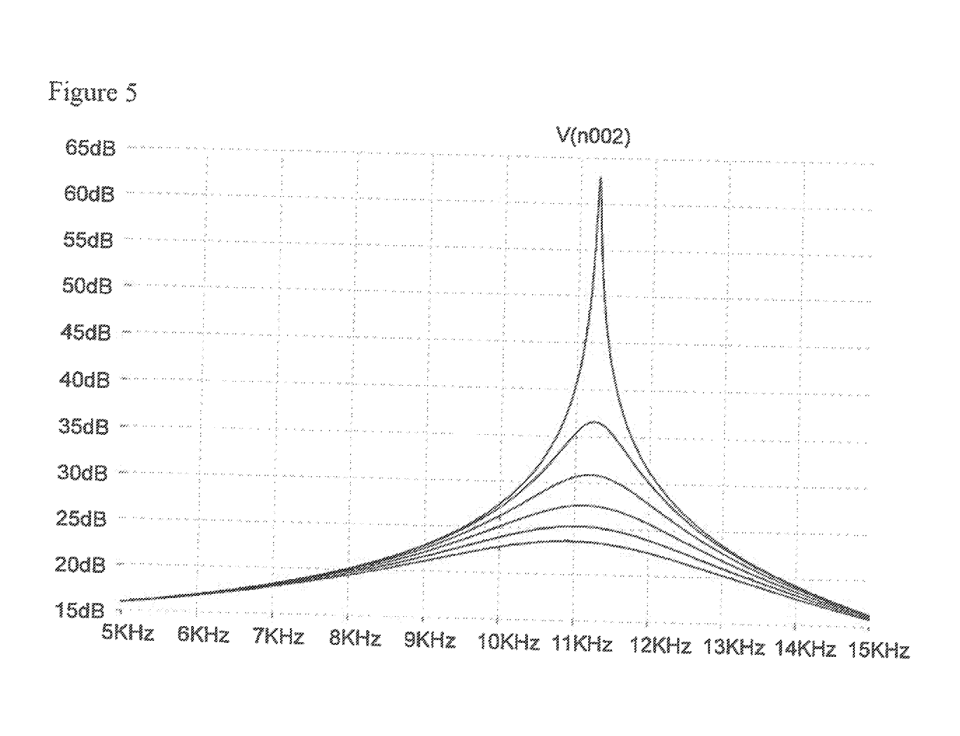

FIG. 5: influence of the quality of a resonant circuit on the transfer characteristic.

FIG. 1 shows a schematic block diagram of a measuring device 1. An alternating voltage generator 11, the alternating voltage of which can be set, supplies a measuring coil 21 via an amplifier 12. The measuring coil 21 is connected to an adjustable capacitor 22. The measuring coil 21 is magnetically coupled to a core 3. The measuring coil 21, the variable capacitor 22 and the core 3 together form a resonant circuit 2,

A network analyser 14 is connected to the resonant circuit 2 via a coupling circuit 13 which serves the impedance matching. The network analyser 14 has a control and display device 15, in order to present the measurement results.

In the control and display device, a temperature sensor 16 is arranged, in order to measure the ambient temperature. On the basis of the temperature measurement, temperature fluctuations can be recorded and computationally compensated for.

FIG. 2 schematically shows the positioning of the measuring coil 21 in a sheet iron core 3. In FIG. 2, the sheet iron core 3 is formed as a toroidal core. Alternatively, it is also possible to use and measure a conventional El core or other geometrical core shapes.

The measuring coil 21 is formed as an air coil and has a wire winding 211. This winding can, for example, consist of an insulated enameled copper wire. At the side of the measuring coil, a shielding 212 is arranged, which ensures that the magnetic flux of the coil is conducted into the core 3. The iron coil 21 is electrically connected to the measuring device 1 via an electrical connection not shown in FIG. 2.

FIG. 3 shows a frequency response of the resonant circuit 2 by way of example. The example shown is the frequency transfer characteristic of an LC circuit connected to a parallel resonant circuit. The frequency range is plotted on the x-axis. The y-axis shows the amplitude of the resulting alternating voltage on the resonant circuit itself. The range of the resonant frequency can be read off through the highest amplitude.

The frequencies f₁ and f₂ marked in FIG. 3 denote those frequencies at which the amplitude has dropped by 3 dB on both sides of the resonant frequency. This so-called 3 dB bandwidth can be simply measured via the network analyser. This bandwidth is a direct measure for the quality of the resonant circuit and thus for the losses of the respective core. The narrower this bandwidth compared to the resonant frequency, i.e. the closer the frequencies f₁ and f₂ are to each other, the higher the quality of the resonant circuit and the smaller the core losses. If the core losses increase, the bandwidth of the resonant circuit thus also increases. This can be simply determined through an increase in the difference between the frequencies f₂-f₁.

FIG. 4 is a graph showing, by way of example, the influence of a change in impedance on the resonant frequency of a resonant circuit. An increase in the impedance of the coil in a resonant circuit leads to a reduction in the resonant frequency.

FIG. 5 is a graph showing, by way of example, a frequency transfer characteristic of an attenuated resonant circuit in the case of different attenuations. The greater the attenuation of the resonant circuit, the smaller the resonance step-up in the range of the resonant frequency. This deviation in the resonance step-up can also be easily determined using measurement technology.

On the basis of the changed quality (Q) and the change in resonant frequency, with the measurement method according to the invention, there are two factors that can be simply accessed using measurement technology, in order to determine the losses in a core with high accuracy.

### LIST OF REFERENCE NUMBERS

1 measuring device

11 alternating frequency generator I high frequency generator

12 amplifier

13 coupling circuit

14 network analyser

15 control and/or display device

16 temperature sensor

2 resonant circuit

21 measuring coil

211 winding

212 shielding

22 adjustable capacitor

3 core/laminated core

f₁, f₂ frequency of the 3 dB point

1. Measurement method for determining laminated core losses,
wherein a magnetic coupling is produced between a measuring coil connected to a capacitor to form a resonant circuit and a laminated core and the measuring coil is then acted upon by an alternating voltage, and
wherein at least one of a resonant frequency of the resonant circuit or a quality of the resonant circuit is measured and loss of the laminated core is determined on the basis of the at least one of the measured resonant frequency or the measured quality.

2. Measurement method according to claim 1,
wherein the resonant frequency of the resonant circuit is measured by changing the capacitance of the capacitor or by changing the frequency of the alternating voltage.

3. Measurement method according to claim 1,
wherein the quality of the resonant circuit is measured through measurement of the bandwidth of a frequency transfer characteristic of the resonant circuit.

4. Measurement method according to claim 3,
wherein the quality of the resonant circuit is determined by measurement of 3 dB bandwidth or 6 dB bandwidth.

5. Measurement method according to claim 1,
wherein the magnetic coupling is produced by introducing the measuring coil into an internal space of the laminated core.

6. Measurement method according to claim 1, wherein
at least one of the resonant frequency or the quality of the resonant circuit is measured at different angle positions of the measuring coil relative to the laminated core, or,
during the measurement of the at least one of the resonant frequency or of the quality, a given angle position of the measuring coil relative to the laminated core is varied.

7. Measuring device formed to carry out a measurement method,
wherein, in the measurement method,
a magnetic coupling is produced between a measuring coil connected to a capacitor to form a resonant circuit and a laminated core and the measuring coil is then acted upon by an alternating voltage, and
at least one of a resonant frequency of the resonant circuit or a quality of the resonant circuit is measured and a loss of the laminated core is determined on the basis of the at least one of the measured resonant frequency or the measured quality, and
wherein the measuring device comprises at least one of a control or display device for displaying measurement results, as well as an alternating voltage generator and the measuring coil.

8. Measuring device according to claim 7,
wherein the measuring coil is connected to a capacitor to form a parallel resonant circuit or a series resonant circuit.

9. Measuring device according to claim 7,
wherein the capacitor is formed as an automatically adjustable capacitor.

10. Measuring device according to claim 7,
wherein the measuring device comprises a network analyser which is connected to the resonant circuit in order to measure at least one of the resonant frequency or the quality of the resonant circuit.

11. Measuring device according to claim 10,
wherein the resonant circuit is connected to an impedance matching unit via a circuit.

12. Measuring device according to claim 7,
wherein the measuring device has a mounting fixture for holding at least one of the laminated core or the measuring coil.

13. Measuring device according to claim 12,
wherein the mounting fixture has an actuator for rotating the laminated core, in order to allow a measurement at different angle positions between the measuring coil and the laminated core.

14. Measuring device according to claim 12, wherein the mounting fixture has an actuator for rotating the measuring coil, in order to allow a measurement at different angle positions between the measuring coil and the laminated core.

15. Measuring device according to claim 7,
wherein the measuring coil is formed as an air coil.

16. Measuring device according to claims 7,
wherein the mounting fixture has a shielding mechanism, in order to shield at least one of the laminated core or the measuring coil.

17. Measuring device according to claim 7,
wherein the measuring device has a temperature sensor and is formed such that the measuring device automatically corrects measured value deviations caused by temperature fluctuations.

18. Production method for laminated cores,
wherein individual magnetic steel sheet slats are provided with an insulation and stacked to form the laminated cores, and
wherein losses of the laminated cores are then measured with a measuring device formed to carry out a measurement method,
wherein, in the measurement method,
a magnetic coupling is produced between a measuring coil connected to a capacitor to form a resonant circuit and a given laminated core and the measuring coil is then acted upon by an alternating voltage, and
at least one of a resonant frequency of the resonant circuit or a quality of the resonant circuit is measured and loss of the given laminated core is determined on the basis of the at least one of the measured resonant frequency or the measured quality,
wherein the measuring device comprises at least one of a control or display device for displaying measurement results, as well as an alternating voltage generator and the measuring coil.

19. Production method according to claim 18,
wherein the losses of the laminated cores are measured before the laminated cores are provided with a winding.

20. Production method according to claim 18,
wherein a limit value is set for losses of the given laminated core, and each of the given laminated core, the losses of which exceed the limit value, is at least one of identified as being defective or discarded.

21. Production method according to claim 18,
wherein for quality assurance, for each given laminated core measured, a measured loss value is stored, and several measurement values are statistically evaluated.

22. Measurement method according to claim 3,
wherein the quality of the resonant circuit is measured by determining a first frequency (f₁) above and a second frequency (f₂) below the resonant frequency of the resonant circuit at which an amplitude of the alternating voltage is the same size in each case.

23. Measuring device according to claim 9,
wherein the capacitor is formed as a variable capacitor or as a capacitance diode.

24. Measuring device according to claim 10,
wherein the network analyser is connected to at least one of the measuring coil or the capacitor in order to measure the at least one of the resonant frequency or the quality of the resonant circuit.

25. Measuring device according to claim 11,
wherein the circuit is connected to the impedance matching unit between the resonant circuit and the network analyser.

26. Measuring device according to claim 15,
wherein the measuring coil is formed as a shielded air coil.
